(19) United States
(12) Patent Application Publication
(10) Pub. No.: US 2023/0403818 A1
(43) Pub. Date: Dec. 14, 2023

(54) LIQUID COOLING HEAT EXCHANGE DEVICE AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Ji LIAN, Zhangjiakou City (CN); Tao LU, Zhangjiakou City (CN)

(21) Appl. No.: 18/207,702

(22) Filed: Jun. 9, 2023

(30) Foreign Application Priority Data
Jun. 10, 2022 (CN) 202210657309.2

(51) Int. Cl. H05K 7/20

(52) U.S. Cl. CPC H05K 7/20272; H05K 7/20263; H05K 7/20836; H05K 7/20781

(57) ABSTRACT

The present disclosure discloses a liquid cooling heat exchange device and a data center. The liquid cooling heat exchange device at least includes a box body, a heat exchange component, a pump body, a filtering component, and a control box. The heat exchange component is provided with an internal liquid inlet, an internal liquid outlet, an external liquid inlet, and an external liquid outlet. The heat exchange component is positioned between the pump body and the filtering component, and the control box is positioned directly above the pump body or the filtering component. The internal liquid inlet is communicated with one end of an internal liquid return pipeline, the pump body is connected in series to the internal liquid return pipeline, the internal liquid outlet is communicated with one end of the internal liquid inlet pipeline, and the filtering component is connected in series to the internal liquid inlet pipeline.

### CROSS-REFERENCE TO RELATED APPLICATION

This application claims priority to Chinese Patent Application No. 202210657309.2, titled “LIQUID COOLING HEAT EXCHANGE DEVICE AND DATA CENTER” and filed to the China National Intellectual Property Administration on Jun. 10, 2022, the entire contents of which are incorporated herein by reference.

### TECHNICAL FIELD

The present disclosure relates to the field of heat exchange device, and more particularly, to a liquid cooling heat exchange device and a data center.

### BACKGROUND

With the improvement of energy consumption requirements, traditional air cooling modes are difficult to meet increasing computing power requirements, and the data center refrigeration industry will usher in a reshuffle, and liquid cooling will gradually be more widely used.

To realize cooling effects of liquid coolants in a liquid-cooled server container during year-round operation, it is required to connect the liquid-cooled server container to an external heat dissipation system for heat exchange through a liquid cooling heat exchange device, such that a temperature of the liquid coolants in the liquid-cooled server container is controlled within a reasonable range to ensure normal operation of a liquid-cooled server.

However, most of components in the existing liquid cooling heat exchange device are sequentially arranged side by side, which leads to a larger contour dimension and thus having an adverse impact on number of servers arranged in a data center.

### SUMMARY

An objective of the present disclosure is to provide a liquid cooling heat exchange device and a data center, to reduce volume of the liquid cooling heat exchange device, thereby increasing number of servers arranged in the data center.

To achieve the above objective, one aspect of the present disclosure provides a liquid cooling heat exchange device, which at least includes a box body, a heat exchange component, a pump body, a filtering component, and a control box. The heat exchange component is provided with an internal liquid inlet, an internal liquid outlet, an external liquid inlet, and an external liquid outlet. The heat exchange component, the pump body, the filtering component and the control box are installed in the box body, where the heat exchange component is positioned between the pump body and the filtering component, and the control box is positioned directly above the pump body or the filtering component. The internal liquid inlet is communicated with one end of an internal liquid return pipeline, the pump body is connected in series to the internal liquid return pipeline, the internal liquid outlet is communicated with one end of the internal liquid inlet pipeline, and the filtering component is connected in series to the internal liquid inlet pipeline. The external liquid inlet is communicated with one end of an external liquid inlet pipeline, and the external liquid outlet is communicated with one end of an external liquid return pipeline. A projection of the internal liquid return pipeline, a projection of the internal liquid inlet pipeline, a projection of the external liquid inlet pipeline and a projection of the external liquid return pipeline on a plane where the pump body and the filtering component are on are positioned between the pump body and the filtering component.

As a further improvement of the technical solutions, other end of the internal liquid return pipeline and other end of the internal liquid inlet pipeline are respectively connected to a pipeline joint through a pipeline connector, and the pipeline joint connected to the internal liquid return pipeline and the pipeline joint connected to the internal liquid inlet pipeline are both positioned on a same side of the box body. The pipeline joint is a right-angled joint such that the pipeline joint is rotatable by 180 degrees around other end of a pipeline connected thereto during installation.

As a further improvement of the technical solutions, the internal liquid return pipeline, the internal liquid inlet pipeline, the external liquid inlet pipeline and the external liquid return pipeline respectively comprise a hard pipeline and a hose pipeline, where in the internal liquid return pipeline, two ends of the pump body are respectively connected to the hose pipeline.

As a further improvement of the technical solutions, other end of the external liquid inlet pipeline and other end of the external liquid return pipeline are respectively positioned on the same side of the box body.

As a further improvement of the technical solutions, a first temperature sensor is connected in series to the internal liquid return pipeline, and a second temperature sensor is connected in series to the internal liquid inlet pipeline. An electrically-controlled regulating valve is connected in series to the external liquid inlet pipeline. The control box is electrically connected to the pump body, the first temperature sensor, the second temperature sensor and the electrically-controlled regulating valve, respectively.

As a further improvement of the technical solutions, the internal liquid inlet pipeline and/or the internal liquid return pipeline are provided with a first branch, and the first branch is connected to a liquid charging/discharging port. The liquid charging/discharging port includes a liquid charging/discharging globe valve and a quick connect coupling, where one end of the liquid charging/discharging globe valve is communicated with the first branch, and other end of the liquid charging/discharging globe valve is communicated with the quick connect coupling.

As a further improvement of the technical solutions, a conductivity meter is connected in series to the internal liquid inlet pipeline; and the conductivity meter is positioned between the filtering component and the other end of the internal liquid inlet pipeline.

As a further improvement of the technical solutions, a plurality of on-off valves are connected in series to the internal liquid return pipeline, the internal liquid inlet pipeline, the external liquid inlet pipeline and the external liquid return pipeline, respectively; and the plurality of on-off valves are sequentially arranged at intervals along the corresponding pipelines.

As a further improvement of the technical solutions, the internal liquid inlet pipeline and/or the internal liquid return pipeline are provided with a second branch, and the second branch is connected to a pressure sensor through a ball valve.

To achieve the above objective, another aspect of the present disclosure also provides a data center, which includes a liquid-cooled server container and the liquid cooling heat exchange device. The other end of the internal liquid return pipeline and the other end of the internal liquid inlet pipeline are respectively communicated with an interior of the liquid-cooled server container.

As can be seen, in the technical solutions provided by the present disclosure, the heat exchange component is arranged between the pump body and the filtering component, the control box is positioned directly above the pump body or the filtering component, and the control box is installed based on a height difference between the heat exchange component and the pump body and a height difference between the heat exchange component and the filtering component, to rationally arrange space and reduce space occupation. Meanwhile, the projection of the internal liquid return pipeline, the projection of the internal liquid inlet pipeline, the projection of the external liquid inlet pipeline and the projection of the external liquid return pipeline on the plane where the pump body and the filtering component are on are positioned between the pump body and the filtering component, thereby further limiting a setting range of the pipelines and further reducing the volume of the liquid cooling heat exchange device, such that the number of the servers arranged in the data center is increased in the case of a certain area of the data center.

Further, the filtering component is connected in series to the internal liquid inlet pipeline, such that the filtering component filters a liquid coolant entering the liquid-cooled server container from an internal circulating liquid, to ensure cleanliness of the liquid coolant entering the liquid-cooled server container.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic front view of a liquid cooling heat exchange device according to an embodiment provided by the present disclosure;

FIG. 2 is a schematic right view of the liquid cooling heat exchange device according to an embodiment provided by the present disclosure;

FIG. 3 is an enlarged view of Part A of FIG. 2;

FIG. 4 is a schematic left view of the liquid cooling heat exchange device according to an embodiment provided by the present disclosure;

FIG. 5 is a schematic diagram showing an external circulation flow direction of the liquid cooling heat exchange device according to an embodiment provided by the present disclosure;

FIG. 6 is a schematic diagram showing an internal circulation flow direction of the liquid cooling heat exchange device according to an embodiment provided by the present disclosure; and

FIG. 7 is a schematic structural diagram showing connection between the liquid cooling heat exchange device and a liquid-cooled server container according to an embodiment provided by the present disclosure.

Reference numerals in the drawings: box body 1; heat exchange component 2; internal liquid inlet 21; internal liquid outlet 22; external liquid inlet 23; external liquid outlet 24; pump body 3; filtering component 4; control box 5; internal liquid return pipeline 6; first temperature sensor 61; on-off valve 62; ball valve 63; pressure sensor 64; internal liquid inlet pipeline 7; pipeline connector 71; pipeline joint 72; second temperature sensor 73; liquid charging/discharging port 74; liquid charging/discharging globe valve 741; quick connect coupling 742; conductivity meter 75; external liquid inlet pipeline 8; electronically-controlled regulating valve 81; external liquid return pipeline 9; and liquid-cooled server container 10.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

With the improvement of energy consumption requirements, traditional air cooling modes are difficult to meet increasing computing power requirements, and the data center refrigeration industry will usher in a reshuffle, and liquid cooling will gradually be more widely used.

To realize cooling effects of liquid coolants in a liquid-cooled server container during year-round operation, it is required to connect the liquid-cooled server container to an external heat dissipation system for heat exchange through a liquid cooling heat exchange device, such that a temperature of the liquid coolants in the liquid-cooled server container is controlled within a reasonable range to ensure normal operation of a liquid-cooled server.

However, most of components in the existing liquid cooling heat exchange device are sequentially arranged side by side, which leads to a larger contour dimension and thus having an adverse impact on number of servers arranged in a data center. In addition, in daily operation of the existing liquid cooling heat exchange device, unexpected situations often happen, for example, components are damaged or need to be maintained. During maintenance, a liquid coolant in the entire liquid cooling heat exchange device generally needs to be discharged, which is cumbersome in operation and low in efficiency.

Based on the above problems, there is an urgent need for a liquid cooling heat exchange device and a data center to reduce volume of the liquid cooling heat exchange device, thereby increasing number of servers arranged in the data center and improving maintenance efficiency.

The technical solutions in the embodiments of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

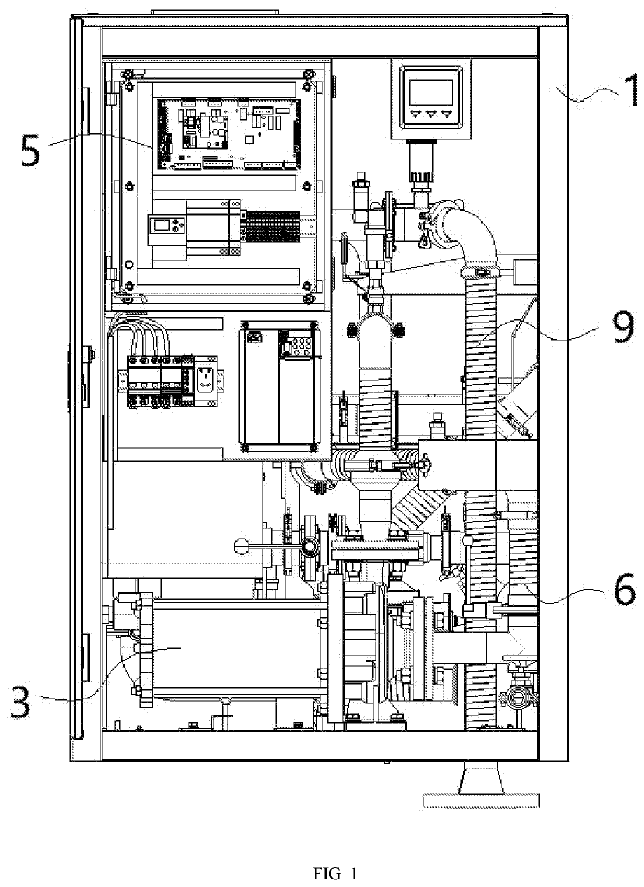

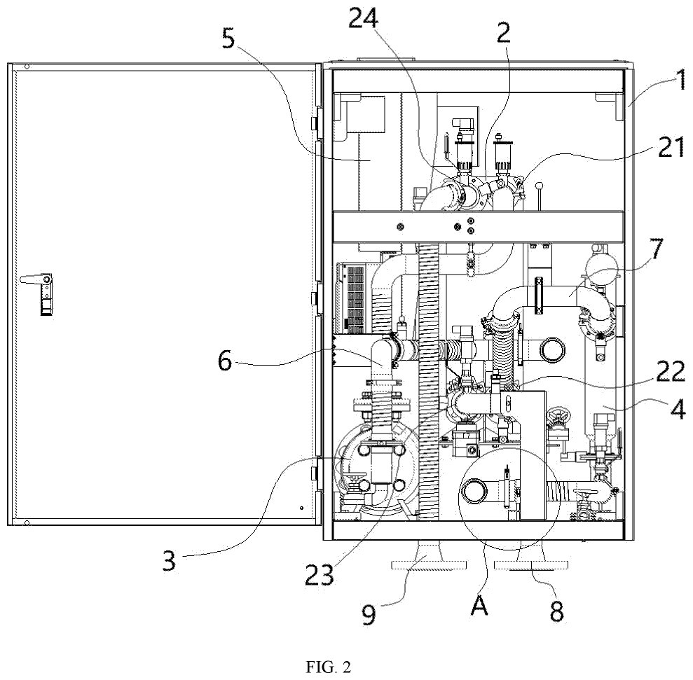

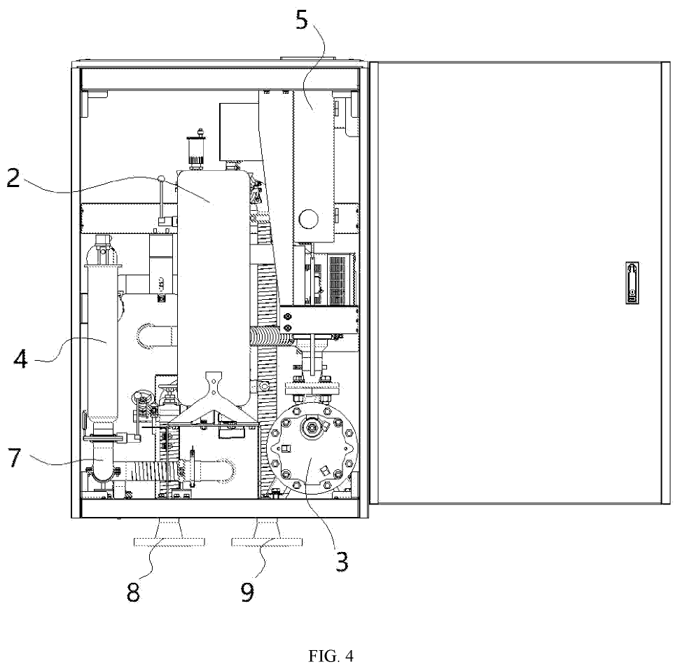

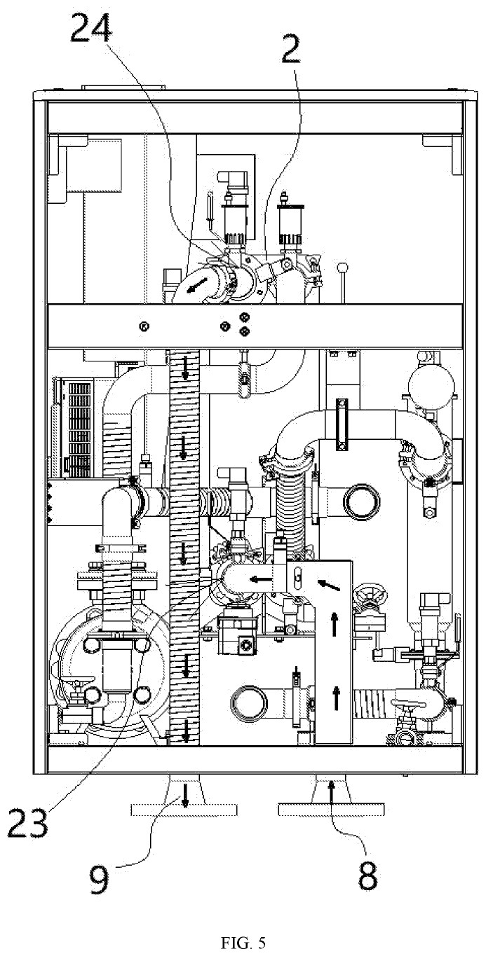

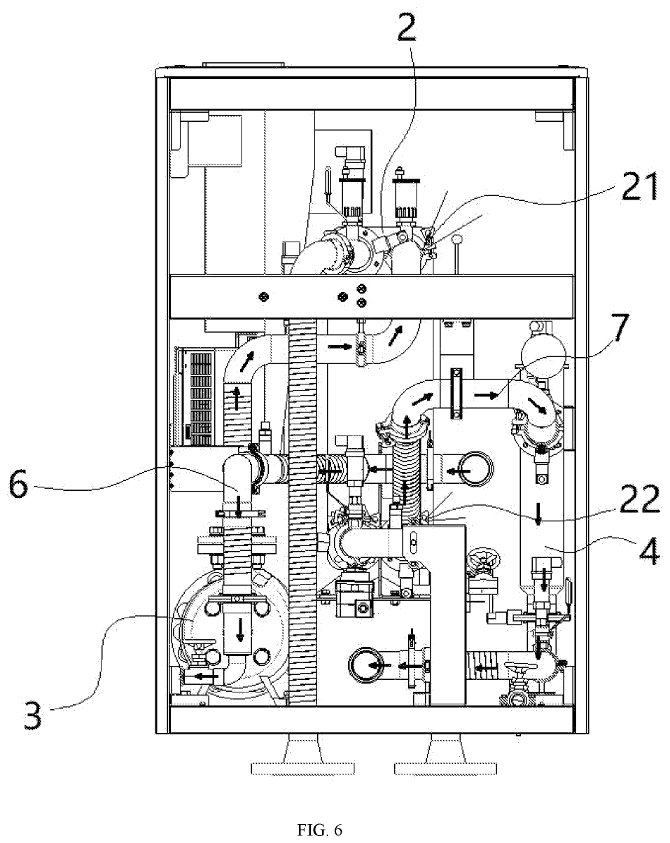

In an implementable embodiment, referring to FIGS. 1 to 6, a liquid cooling heat exchange device may at least include a box body 1, a heat exchange component 2, a pump body 3, a filtering component 4, and a control box 5. The heat exchange component 2 is provided with an internal liquid inlet 21, an internal liquid outlet 22, an external liquid inlet 23, and an external liquid outlet 24. The internal liquid inlet 21 and the internal liquid outlet 22 communicate with each other inside the heat exchange component 2, the external liquid inlet 23 and the external liquid outlet 24 communicate with each other inside the heat exchange component 2, and neither the internal liquid inlet 21 nor the internal liquid outlet 22 communicates with the external liquid inlet 23 or the external liquid outlet 24, such that an internal circulating coolant and an external circulating coolant can exchange heat without mingling with each other.

The heat exchange component 2, the pump body 3, the filtering component 4 and the control box 5 are installed in the box body 1, where the heat exchange component 2 is positioned between the pump body 3 and the filtering component 4, and the control box 5 is positioned directly above the pump body 3 or the filtering component 4. Because there is certain height space between the heat exchange component 2 and the pump body 3 and between the heat exchange component 2 and the filtering component 4, the control box 5 may be installed within the height space directly above the pump body 3 or the filtering component 4, thereby rationally utilizing space and reducing the volume of the liquid cooling heat exchange device.

The internal liquid inlet 21 is communicated with one end of the internal liquid return pipeline 6, other end of the internal liquid return pipeline 6 is communicated with a liquid-cooled server container 10, the internal liquid outlet 22 is communicated with one end of the internal liquid inlet pipeline 7, and other end of the internal liquid inlet pipeline 7 is communicated with the liquid-cooled server container 10, thereby forming an internal circulation loop. The pump body 3 is connected in series to the internal liquid return pipeline 6, and the pump body 3 is configured to provide power for circulation of the liquid coolant in the internal circulation loop. The filtering component 4 is connected in series to the internal liquid inlet pipeline 7 to filter the liquid coolant entering the liquid-cooled server container 10.

The external liquid inlet 23 is communicated with one end of an external liquid inlet pipeline 8, and the external liquid outlet 24 is communicated with one end of an external liquid return pipeline 9. Other end of the external liquid inlet pipeline 8 and other end of the external liquid return pipeline 9 may be communicated with an external heat exchange component such as a cooling tower device or the like.

A projection of the internal liquid return pipeline 6, a projection of the internal liquid inlet pipeline 7, a projection of the external liquid inlet pipeline 8 and a projection of the external liquid return pipeline 9 on a plane where the pump body 3 and the filtering component 4 are on are positioned between the pump body 3 and the filtering component 4. In this way, installation ranges of the pipelines communicating with the internal liquid return pipeline 6, the internal liquid inlet pipeline 7, the external liquid inlet pipeline 8 and the external liquid return pipeline 9 are defined, which further reduces the volume of the liquid cooling heat exchange device, such that the number of the servers arranged in the data center is increased in the case of a certain area of the data center.

In practical application, the heat exchange component 2 may adopt a plate heat exchanger. The filtering component 4 may employ a vertical filter. Meanwhile, to ensure that the internal liquid return pipeline 6, the internal liquid inlet pipeline 7, the external liquid inlet pipeline 8 and the external liquid return pipeline 9 can be installed within the ranges defined between the pump body 3 and the filtering component 4, the internal liquid return pipeline 6, the internal liquid inlet pipeline 7, the external liquid inlet pipeline 8 and the external liquid return pipeline 9 may each comprise a hard pipeline and a hose pipeline respectively, where the hose pipeline can compensate for size and assembly errors, thus facilitating layout and installation of the pipelines. The hard pipeline may be configured to connect components such as a temperature sensor, a valve body and a pressure sensor.

It is to be noted that in the internal liquid return pipeline 6, two ends of the pump body 3 may be respectively connected to the hose pipeline, such that the hose pipelines positioned at the two ends of the pump body 3 can reduce adverse impacts of vibration caused by the operation of the pump body 3 on other parts, which is beneficial to the stable operation of the device.

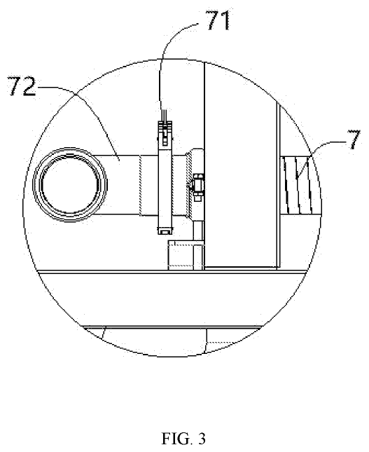

In an implementable embodiment, referring to FIG. 3 again, other end of the internal liquid return pipeline 6 and other end of the internal liquid inlet pipeline 7 are respectively connected to a pipeline joint 72 through a pipeline connector 71, and the pipeline joint 72 connected to the internal liquid return pipeline 6 and the pipeline joint 72 connected to the internal liquid inlet pipeline 7 are both positioned on a same side of the box body 1, thereby facilitating the connection to the liquid-cooled server container 10 from the same side, avoiding additional pipelines and saving costs.

Further, the pipeline joint 72 is a right-angled joint such that the pipeline joint 72 is rotatable by 180 degrees around other end of a pipeline connected thereto during installation. In actual use, based on a side (left side or right side) of the liquid-cooled server container 10 positioned on the liquid cooling heat exchange device, the pipeline joint 72 may be adjusted toward the liquid-cooled server container 10, and next the pipeline joint 72 is aligned and then connected. In this way, the liquid-cooled server container 10 on either side of the two sides can be used, which has better universality.

The pipeline joint 72 may be flanged connection, clamp connection or the like.

Similarly, the other end of the external liquid inlet pipeline 8 and the other end of the external liquid return pipeline 9 are respectively positioned on the same side of the box body 1, such that additional pipelines can be avoided when the external liquid inlet pipeline 8 and the external liquid return pipeline 9 are connected to an external heat exchange device, thereby saving the costs.

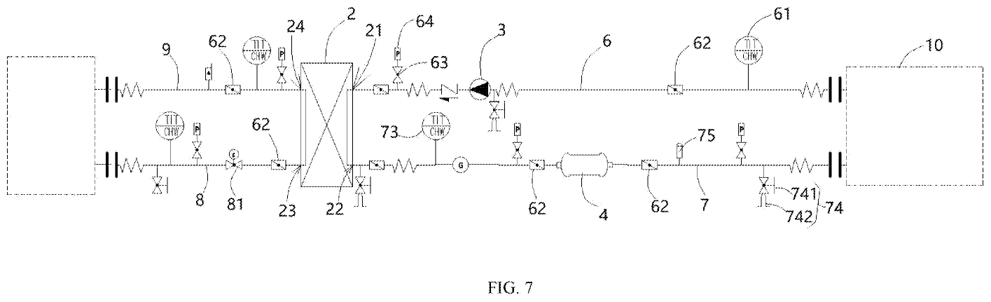

In an implementable embodiment, as shown in FIG. 7, a first temperature sensor 61 is connected in series to the internal liquid return pipeline 6, and a second temperature sensor 73 is connected in series to the internal liquid inlet pipeline 7. An electrically-controlled regulating valve 81 is connected in series to the external liquid inlet pipeline 8. The control box 5 is electrically connected to the pump body 3, the first temperature sensor 61, the second temperature sensor 73 and the electrically-controlled regulating valve 81, respectively.

The control box 5 receives, in real time, a temperature of a liquid outlet of the liquid-cooled server container 10 detected by the first temperature sensor 61, and the temperature of the liquid outlet of the liquid-cooled server container 10 may represent heat dissipation of the liquid coolant in the internal circulation loop to a device in the liquid-cooled server container 10. When it is determined that there is a differential between the temperature detected by the first temperature sensor 61 and a first preset temperature of the system, the control box 5 may calculate rotational speed adjustment of the pump body 3 based on a PID algorithm to adjust the rotational speed of the pump body 3, thereby adjusting a flow rate of the pump body 3 and further adjusting refrigerating effects of the liquid-cooled server container 10.

Meanwhile, the control box 5 also receives a temperature of the internal liquid outlet 22 detected by the second temperature sensor 73, where the temperature of the internal liquid outlet 22 may represent heat exchange of a liquid coolant in an external circulation loop to the liquid coolant in the internal circulation loop.

When it is determined that there is a differential between the temperature detected by the second temperature sensor 73 and a second preset temperature of the system, the control box 5 may calculate opening adjustment of the electronically-controlled regulating valve 81 based on the PID algorithm to adjust opening of the electronically-controlled regulating valve 81, thereby adjusting a flow rate of the electronically-controlled regulating valve 81. Thus, the flow rate of the external circulation loop and the flow rate of the internal circulation loop can be adjusted simultaneously based on temperature monitoring, and the temperature of the liquid coolant used for heat exchange of the device in the liquid-cooled server container 10 and the heat exchange temperature of the external circulation loop to the internal circulation loop can be reasonably adjusted to ensure the normal operation of the device in the liquid-cooled server container 10.

Further, after long-term operation, the liquid coolant in the internal circulation loop may be volatilized, resulting in a shortage of the liquid coolant. To facilitate replenishment of the liquid coolant, a first branch is provided on the internal liquid inlet pipeline 7 and/or the internal liquid return pipeline 6, and a liquid charging/discharging port 74 is connected to the first branch.

Specifically, the liquid charging/discharging port 74 includes a liquid charging/discharging globe valve 741 and a quick connect coupling 742, where one end of the liquid charging/discharging globe valve 741 is communicated with the first branch, and other end of the liquid charging/discharging globe valve 741 is communicated with the quick connect coupling 742. Thus, when it is required to replenish the liquid coolant, an external liquid replenishment device port may be connected to the quick connect coupling 742, and then the liquid charging/discharging globe valve 741 is opened to replenish the liquid coolant. After the replenishment of the liquid coolant is completed, the liquid charging/discharging globe valve 741 is first closed, and then the external liquid replenishment device port is removed from the quick connect coupling 742.

Further, a conductivity meter 75 is connected in series to the internal liquid inlet pipeline 7. The conductivity meter 75 is positioned between the filtering component 4 and the other end of the internal liquid inlet pipeline 7 to measure conductivity of the liquid entering the liquid-cooled server container 10 from the internal liquid inlet pipeline 7. When a value of the measured conductivity is higher than a preset value, an alarm may be triggered, and an operator may handle this problem to ensure the normal operation of the server in the liquid-cooled server container 10.

The internal liquid inlet pipeline 7 and/or the internal liquid return pipeline 6 are provided with a second branch, which is connected to a pressure sensor 64 through a ball valve 63. The ball valve 63 is normally open, and the corresponding ball valve 63 may be closed when the pressure sensor 64 needs maintenance, to facilitate maintenance and repair.

Further, a plurality of on-off valves 62 are connected in series to the internal liquid return pipeline 6, the internal liquid inlet pipeline 7, the external liquid inlet pipeline 8 and the external liquid return pipeline 9, respectively. The plurality of on-off valves 62 are sequentially arranged at intervals along the corresponding pipelines, such that during subsequent maintenance and repair, it is not required to discharge all the liquid for maintenance and repair, but only the on-off valves 62 at two ends of a corresponding maintenance point need to be closed, which makes the maintenance and repair more convenient.

Based on the same inventive concept, referring to FIG. 7, the present disclosure also provides a data center, which includes the liquid-cooled server container 10 and the liquid cooling heat exchange device described above. The other end of the internal liquid return pipeline 6 and the other end of the internal liquid inlet pipeline 7 are respectively communicated with an interior of the liquid-cooled server container 10.

It should be pointed out that reference may be made to the above contents for specific structures of the liquid cooling heat exchange device, which are not to be described in detail here.

As can be seen, in the technical solutions provided by the present disclosure, the heat exchange component is arranged between the pump body and the filtering component, the control box is positioned directly above the pump body or the filtering component, and the control box is installed based on a height difference between the heat exchange component and the pump body and a height difference between the heat exchange component and the filtering component, to rationally arrange space and reduce space occupation. Meanwhile, the projection of the internal liquid return pipeline, the projection of the internal liquid inlet pipeline, the projection of the external liquid inlet pipeline and the projection of the external liquid return pipeline on the plane where the pump body and the filtering component are on are positioned between the pump body and the filtering component, thereby further limiting a setting range of the pipelines and further reducing the volume of the liquid cooling heat exchange device, such that the number of the servers arranged in the data center is increased in the case of a certain area of the data center.

Further, the filtering component is connected in series to the internal liquid inlet pipeline, such that the filtering component filters a liquid coolant entering the liquid-cooled server container from an internal circulating liquid, to ensure cleanliness of the liquid coolant entering the liquid-cooled server container.

Meanwhile, the internal liquid return pipeline, the internal liquid inlet pipeline, the external liquid inlet pipeline and the external liquid return pipeline may each comprise a hard pipeline and a hose pipeline respectively, where the hose pipeline can compensate for size and assembly errors, thus facilitating layout and installation of the pipelines. Further, in the internal liquid return pipeline, two ends of the pump body may be respectively connected to the hose pipeline, such that the hose pipelines positioned at the two ends of the pump body can reduce adverse impacts of vibration caused by the operation of the pump body on other parts, which is beneficial to the stable operation of the device.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A liquid cooling heat exchange device, comprising at least a box body (1), a heat exchange component (2), a pump body (3), a filtering component (4) and a control box (5), wherein the heat exchange component (2) is provided with an internal liquid inlet (21), an internal liquid outlet (22), an external liquid inlet (23) and an external liquid outlet (24); the heat exchange component (2), the pump body (3), the filtering component (4) and the control box (5) are installed in the box body (1), the heat exchange component (2) is positioned between the pump body (3) and the filtering component (4), and the control box (5) is positioned directly above the pump body (3) or the filtering component (4);
the internal liquid inlet (21) is communicated with one end of an internal liquid return pipeline (6), the pump body (3) is connected in series to the internal liquid return pipeline (6), the internal liquid outlet (22) is communicated with one end of the internal liquid inlet pipeline (7), and the filtering component (4) is connected in series to the internal liquid inlet pipeline (7);
the external liquid inlet (23) is communicated with one end of an external liquid inlet pipeline (8), and the external liquid outlet (24) is communicated with one end of an external liquid return pipeline (9); and
a projection of the internal liquid return pipeline (6), a projection of the internal liquid inlet pipeline (7), a projection of the external liquid inlet pipeline (8) and a projection of the external liquid return pipeline (9) on a plane where the pump body (3) and the filtering component (4) are on are positioned between the pump body (3) and the filtering component (4).

2. The liquid cooling heat exchange device according to claim 1, wherein other end of the internal liquid return pipeline (6) and other end of the internal liquid inlet pipeline (7) are respectively connected to a pipeline joint (72) through a pipeline connector (71), and the pipeline joint (72) connected to the internal liquid return pipeline (6) and the pipeline joint (72) connected to the internal liquid inlet pipeline (7) are both positioned on a same side of the box body (1); and
the pipeline joint (72) is a right-angled joint such that the pipeline joint (72) is rotatable by 180 degrees around other end of a pipeline connected thereto during installation.

3. The liquid cooling heat exchange device according to claim 2, wherein the internal liquid return pipeline (6), the internal liquid inlet pipeline (7), the external liquid inlet pipeline (8) and the external liquid return pipeline (9) respectively comprise a hard pipeline and a hose pipeline; and
wherein in the internal liquid return pipeline (6), two ends of the pump body (3) are respectively connected to the hose pipeline.

4. The liquid cooling heat exchange device according to claim 3, wherein other end of the external liquid inlet pipeline (8) and other end of the external liquid return pipeline (9) are respectively positioned on the same side of the box body (1).

5. The liquid cooling heat exchange device according to claim 3, wherein a first temperature sensor (61) is connected in series to the internal liquid return pipeline (6), and a second temperature sensor (73) is connected in series to the internal liquid inlet pipeline (7);
an electrically-controlled regulating valve (81) is connected in series to the external liquid inlet pipeline (8); and
the control box (5) is electrically connected to the pump body (3), the first temperature sensor (61), the second temperature sensor (73) and the electrically-controlled regulating valve (81), respectively.

6. The liquid cooling heat exchange device according to claim 5, wherein the internal liquid inlet pipeline (7) and/or the internal liquid return pipeline (6) are provided with a first branch, and the first branch is connected to a liquid charging/discharging port (74); and
the liquid charging/discharging port (74) comprises a liquid charging/discharging globe valve (741) and a quick connect coupling (742), one end of the liquid charging/discharging globe valve (741) is communicated with the first branch, and other end of the liquid charging/discharging globe valve (741) is communicated with the quick connect coupling (742).

7. The liquid cooling heat exchange device according to claim 6, wherein a conductivity meter (75) is connected in series to the internal liquid inlet pipeline (7); and
the conductivity meter (75) is positioned between the filtering component (4) and the other end of the internal liquid inlet pipeline (7).

8. The liquid cooling heat exchange device according to claim 7, wherein a plurality of on-off valves (62) are connected in series to the internal liquid return pipeline (6), the internal liquid inlet pipeline (7), the external liquid inlet pipeline (8) and the external liquid return pipeline (9), respectively; and
the plurality of on-off valves (62) are sequentially arranged at intervals along the corresponding pipelines.

9. The liquid cooling heat exchange device according to claim 8, wherein the internal liquid inlet pipeline (7) and/or the internal liquid return pipeline (6) are provided with a second branch, and the second branch is connected to a pressure sensor (64) through a ball valve (63).

10. A data center comprising a liquid-cooled server container (10) and a liquid cooling heat exchange device, wherein the liquid cooling heat exchange device comprises:
at least a box body (1), a heat exchange component (2), a pump body (3), a filtering component (4) and a control box (5), wherein the heat exchange component (2) is provided with an internal liquid inlet (21), an internal liquid outlet (22), an external liquid inlet (23) and an external liquid outlet (24); the heat exchange component (2), the pump body (3), the filtering component (4) and the control box (5) are installed in the box body (1), the heat exchange component (2) is positioned between the pump body (3) and the filtering component (4), and the control box (5) is positioned directly above the pump body (3) or the filtering component (4);
the internal liquid inlet (21) is communicated with one end of an internal liquid return pipeline (6), the pump body (3) is connected in series to the internal liquid return pipeline (6), the internal liquid outlet (22) is communicated with one end of the internal liquid inlet pipeline (7), and the filtering component (4) is connected in series to the internal liquid inlet pipeline (7);
the external liquid inlet (23) is communicated with one end of an external liquid inlet pipeline (8), and the external liquid outlet (24) is communicated with one end of an external liquid return pipeline (9); and
a projection of the internal liquid return pipeline (6), a projection of the internal liquid inlet pipeline (7), a projection of the external liquid inlet pipeline (8) and a projection of the external liquid return pipeline (9) on a plane where the pump body (3) and the filtering component (4) are on are positioned between the pump body (3) and the filtering component (4);
wherein the other end of the internal liquid return pipeline (6) and the other end of the internal liquid inlet pipeline (7) are respectively communicated with an interior of the liquid-cooled server container (10).

11. The data center according to claim 10, wherein other end of the internal liquid return pipeline (6) and other end of the internal liquid inlet pipeline (7) are respectively connected to a pipeline joint (72) through a pipeline connector (71), and the pipeline joint (72) connected to the internal liquid return pipeline (6) and the pipeline joint (72) connected to the internal liquid inlet pipeline (7) are both positioned on a same side of the box body (1); and
the pipeline joint (72) is a right-angled joint such that the pipeline joint (72) is rotatable by 180 degrees around other end of a pipeline connected thereto during installation.

12. The data center according to claim 11, wherein the internal liquid return pipeline (6), the internal liquid inlet pipeline (7), the external liquid inlet pipeline (8) and the external liquid return pipeline (9) respectively comprise a hard pipeline and a hose pipeline; and
wherein in the internal liquid return pipeline (6), two ends of the pump body (3) are respectively connected to the hose pipeline.

13. The data center according to claim 12, wherein other end of the external liquid inlet pipeline (8) and other end of the external liquid return pipeline (9) are respectively positioned on the same side of the box body (1).

14. The data center according to claim 12, wherein a first temperature sensor (61) is connected in series to the internal liquid return pipeline (6), and a second temperature sensor (73) is connected in series to the internal liquid inlet pipeline (7);
an electrically-controlled regulating valve (81) is connected in series to the external liquid inlet pipeline (8); and
the control box (5) is electrically connected to the pump body (3), the first temperature sensor (61), the second temperature sensor (73) and the electrically-controlled regulating valve (81), respectively.

15. The data center according to claim 14, wherein the internal liquid inlet pipeline (7) and/or the internal liquid return pipeline (6) are provided with a first branch, and the first branch is connected to a liquid charging/discharging port (74); and
the liquid charging/discharging port (74) comprises a liquid charging/discharging globe valve (741) and a quick connect coupling (742), one end of the liquid charging/discharging globe valve (741) is communicated with the first branch, and other end of the liquid charging/discharging globe valve (741) is communicated with the quick connect coupling (742).

16. The data center according to claim 15, wherein a conductivity meter (75) is connected in series to the internal liquid inlet pipeline (7); and
the conductivity meter (75) is positioned between the filtering component (4) and the other end of the internal liquid inlet pipeline (7).

17. The data center according to claim 16, wherein a plurality of on-off valves (62) are connected in series to the internal liquid return pipeline (6), the internal liquid inlet pipeline (7), the external liquid inlet pipeline (8) and the external liquid return pipeline (9), respectively; and
the plurality of on-off valves (62) are sequentially arranged at intervals along the corresponding pipelines.

18. The data center according to claim 17, wherein the internal liquid inlet pipeline (7) and/or the internal liquid return pipeline (6) are provided with a second branch, and the second branch is connected to a pressure sensor (64) through a ball valve (63).
